(19) United States
(12) Patent Application Publication
(10) Pub. No.: US 2026/0338639 A1
(43) Pub. Date: Oct. 29, 2026

(54) Apparatus and Method for Aligning a Test Specimen Axis Relative to the Axis of a Test Stand

(71) Applicant: HORIBA EUROPE GMBH, Darmstadt (DE)

(72) Inventors: Nils Palesch, Oberwiesen (DE); Hendrik Buff, Ober-Ramstadt (DE)

(21) Appl. No.: 19/115,121

(22) PCT Filed: Sep. 26, 2023
(86) PCT No.: PCT/EP2023/076519

§ 371 Date: Mar. 25, 2025

(30) Foreign Application Priority Data
Sep. 28, 2022 (DE) 102022124939.5

(51) Int. Cl. G01M 15/02

(52) U.S. Cl. CPC G01M 15/02

(57) ABSTRACT

The invention relates to an apparatus (2) for aligning the axis (9) of a test specimen (3) relative to the axis (6) of a test stand (1), said apparatus comprising: a first plate (11) which is designed for fastening to a mounting plate (7) of the test stand (1); and a second plate (12) which is designed to fasten the test specimen (3), the first plate (11) and the second plate (12) being positioned flat against one another and being fastened by a fastening device (18), the fastening device (18) allowing at least two fastening states, specifically an alignment state and a fixing state, such that the two plates (11, 12) can be displaced parallel to one another in the alignment state and such that the two plates (11, 12) are fixed relative to one another in the fixing state, and an adjusting device (22) being provided for displacing one of the two plates (11, 12) parallel relative to the other plate (11, 12) in the alignment state.

### TECHNICAL FIELD

The invention relates to an apparatus and a method for aligning a test specimen axis relative to the axis of a test stand.

### BACKGROUND

With the increasing use of electric motors as drives, e.g., for motor vehicles, it is necessary to test and evaluate the drive behavior of electric motors on a test stand, as this has long been the case for combustion engines. In order to keep interference to a minimum, it is necessary for an electric motor to be tested (test specimen) to have its motor axis aligned precisely with the axis of the test stand. The motor axis constitutes the geometric center axis or rotation axis of the motor shaft. Accordingly, the axis of the test stand constitutes the geometric center axis or rotation axis of a test stand shaft. The term “axis” is therefore to be understood as a geometric element that defines the respective position and alignment of an associated shaft.

Incorrect alignment of the two axes, e.g., due to a parallel offset or angular offset of the test specimen axis relative to the test stand axis, can lead to vibrations in the subsequent test procedure, which can cause measurement errors or damage to the test specimen or the test stand.

Accordingly, it is necessary that the electric motor to be tested is installed on the test stand with very high accuracy. This requires much effort when mounting the electric motor, combined with recurring measurements and alignment corrections.

During assembly and alignment of the test specimen, the test stand is also blocked and cannot be used for other testing tasks.

### SUMMARY

The invention is therefore based on the object of specifying a way of easily and conveniently aligning the axis of an electric motor serving as a test specimen relative to the axis of a test stand.

An apparatus and a method are described. In addition, a test stand system is specified in which the apparatus can be used advantageously.

An apparatus for aligning the axis of a test specimen relative to the axis of a test stand is specified, said apparatus comprising a first plate which is configured to fasten to a mounting plate of the test stand; comprising a second plate which is configured for fastening the test specimen; wherein the first plate and the second plate are arranged flat on top of one another and fastened to one another by a fastening device; wherein the fastening device allows at least two fastening states, namely an alignment state and a fixing state, such that the two plates can be displaced parallel relative to one another in the alignment state and such that the two plates are fixed relative to one another in the fixing state; and wherein an adjusting device is provided for displacing one of the two plates parallel relative to the other plate in the alignment state.

The apparatus is therefore suitable for aligning a test specimen axis with a test stand axis. In particular, this can involve the (geometric) axes of the respective shafts if an electric motor with a motor shaft and, on the test stand side, a dynamometer with a corresponding dynamometer shaft are provided as the test specimen. The two axes and therefore the shafts must be aligned with one another as precisely as possible in order to minimize an axial or parallel offset on one hand and an angular offset on the other hand.

The apparatus described comprises neither the test stand nor the test specimen itself. Rather, it serves as a link between the test specimen and the test stand in order to fasten the test specimen to the test stand in a simple manner and acts as a kind of adapter. In particular, the apparatus allows the test specimen to be aligned before it is even mounted on the test stand. As will be explained later, this makes it possible to initially fasten the test specimen to the apparatus and subsequently align it with respect to the apparatus. Thereafter, the aligned test specimen is fastened to the test stand together with the apparatus. Subsequent re-alignment is not necessary.

In particular, the test specimen can be fastened to the second plate of the apparatus and subsequently aligned together with the second plate relative to the first plate. The first plate is then fastened (mounted) to the test stand together with the second plate and the test specimen borne by it. Once alignment has been completed, the entire apparatus with the already mounted and aligned test specimen can be fastened to the mounting plate of the test stand as a single unit. Subsequent re-alignment is no longer necessary, as the test specimen is already in the optimum position in which the test specimen axis is aligned with the test stand axis.

The first plate and the second plate are flatly in contact with one another, i.e., they touch one another extensively across a respective planar contact surface. In this process, it is not absolutely necessary for the plates to be completely flat. They could also have a different contour and, in particular, a different depth.

Displacement of the two plates relative to one another, in particular, the parallel or rotational displacement required in the alignment state, with the aid of the adjusting device is only possible if the fastening device allows the alignment state.

Otherwise, the fastening device fixes the two plates to one another so that displacement of the plates relative to one another is not possible.

Displacement of the two plates in relation to one another takes place in the contact surface, i.e., in the area of contact where the two plates touch one another. The displacement comprises both linear or parallel displacement and a rotational twisting in the plane of the two plates to one another.

The test specimen is initially mounted on the second plate. If the test specimen is an electric motor, it is possible to fasten the electric motor to the second plate via its frontal flange, in particular, by screwing it down. Thereafter, the second plate is connected to the first plate, where the two plates can be fixed to one another by the fastening device. Once the test specimen has been mounted and aligned, the first plate can be fastened to the mounting plate of the test stand.

The fastening device can have at least one screw connection which acts between the first plate and the second plate, with the screw connection being firmly tightened in the fixing state and loosened in the alignment state such that the two plates can be displaced relative to one another. This means that the plates can always be held flat next to one another, where the plates are pressed against one another so tightly by the screw connection in the fixing state that they can no longer be displaced relative to one another. In the alignment state, on the other hand, the screw connection is loosened to such an extent that displacement of the two plates relative to one another is possible. Of course, there should still be a certain amount of friction between the two plates so that the plates do not lose contact with one another. For precise alignment, it is necessary that the plates always remain flatly in contact with one another and that a certain amount of friction is generated between the two plates. Loosening or lifting the plates away from one another should be avoided, as this could cause the plates to tilt relative to one another, so that parallel displacement of the plates would no longer be guaranteed.

The adjusting device can be configured to generate a force between the first plate and the second plate for relative displacement of the two plates. In particular, this can generate a force that extends parallel to the contact surface between the two plates. The adjusting device can be supported on one of the plates and exert a force on the other plate. This makes it possible to displace one plate relative to the other plate. The displacement, for example, can comprise a parallel displacement and/or a rotation of the two plates towards one another.

The adjusting device can have several screw devices, with at least one of the screw devices having a thread mount which is fastened to one of the plates, wherein a screw bolt can be screwed inside the thread mount, and wherein one end face of the screw bolt acts on that one of the two plates to which the thread mount is not fastened, whereby a force can be applied to the plate in question. The screw bolt runs in the thread of the thread mount and, in particular, can be rotated in this thread like a screw. Turning the screw bolt causes it to move axially.

When the screw bolt is in contact with the plate it is acting on, a force acts upon the plate in question on the end face of the screw bolt, causing it to be displaced relative to the other plate.

The thread mount and/or the screw bolt that can be screwed inside the thread mount can be arranged on a side face of the respective plate, with the side face being perpendicular to a contact surface where the two plates touch one another flatly. The force exerted by the screw bolt therefore acts laterally on the plate and thus parallel to the contact surfaces of the two plates.

The geometry of the first plate and the second plate can each correspond to a plate-shaped cuboid, each having two plate surfaces parallel to one another and four side faces connecting the two plate surfaces, wherein the adjusting device can have eight screw devices, two of which are each arranged on a side face of a plate at a distance from one another. In each case, one of the plate surfaces is a contact surface to the respective contact surface of the respective other adjacent plate.

The geometry of the plates does not have to be strictly limited to an exact cuboid. Approximated cuboids, e.g., with recesses or serrations, are also possible.

The decisive factor is that the plates have four side faces that are perpendicular or parallel to one another, so that the screw devices arranged thereon allow any movement of one plate relative to the other plate in the plane. The plates can therefore be displaced or rotated linearly in the x and y directions-if a coordinate system is used-but not in the z direction (which would mean the two plates lifting away from one another).

Typically, the test specimen can be an electric motor. In this process, it is possible that the electric motor has a flange or a frontal flange surface with which the electric motor can be fastened to the second plate.

A support frame can be provided, which is fastened to the second plate. The support frame can serve to reinforce the entire arrangement of the first and second plates. In particular, the support frame can serve to transport the apparatus together with the test specimen mounted on the apparatus. Furthermore, the support frame can be configured to support the test specimen in order to avoid bending and transverse moments on the housing of the test specimen or even the test specimen shaft.

Support elements can be provided on the support frame to support a test specimen fastened to the second plate. These support elements, for example, can be formed by support bolts or support columns and support the test specimen, particularly on its underside, in order to hold and secure it reliably on the support frame.

The apparatus described can be used particularly advantageously as an alignment device for aligning and fastening a test specimen in a test stand system known per se.

A test stand system is specified, comprising an electric motor serving as a test specimen, a test stand for testing the electric motor, a test stand shaft to which a shaft of the electric motor can be fastened for transmitting a motion of the electric motor to the test stand, a mounting plate provided on the test stand, and comprising a device of the aforementioned type as an alignment device for fastening the electric motor to and aligning it with the mounting plate.

Such a test stand, without the aforementioned (alignment) device, is known per se. As a rule, it has a drive or load device, such as a dynamometer, the shaft of which forms the test stand shaft. The test stand shaft constitutes a component of the test stand and can be coupled to the shaft of the test specimen (here: the electric motor), e.g., by means of a suitable coupling. In this way, the movements of the test specimen and the load or drive device are precisely coupled to one another. In particular, the dynamometer can be operated as a load device and thus exert a load torque on the electric motor. In this way, a standard drive situation can be simulated with the electric motor.

In addition or as an alternative, the dynamometer can also be operated as a drive device and exert a drive torque on the electric motor, which, in this case, is not driven. In this way, a coasting mode can be achieved. Naturally, the electric motor serving as the test specimen can also be operated as a generator in order to use a braking load against the driving dynamometer. In this way, the braking behavior of the test specimen can be examined in coasting mode.

In particular, a so-called 4-quadrant operation can thus be achieved, in which the electric motor and the dynamometer can each be operated as a motor or generator in different combinations (motor-motor, motor-generator, generator-motor, generator-generator).

The test stand includes the mounting plate to which the electric motor can be coupled. For this purpose, the alignment device described above can be used to optimally align the electric motor already before it is mounted on the mounting plate. The electric motor is then fastened to the mounting plate together with the alignment device, without the need for any further subsequent adjustment or alignment measures.

The mounting plate can be plate-shaped, but can also be designed as a block or frame. It makes sense for the mounting plate to have a mounting surface to which the alignment device with the electric motor can be fastened.

In the alignment device, the first plate, the second plate, the electric motor fastened to the second plate, and the support frame can constitute a pre-assembled unit which can be fastened as a single unit to the mounting plate. Accordingly, as already explained above, the electric motor can initially be fastened to the second plate. Subsequently, the relative position of the second plate to the first plate is adjusted such that the motor shaft of the electric motor, i.e., the axis of the electric motor, is exactly in the position (parallel position, angular position) in which it must be relative to the first plate in order to achieve the smallest possible offset to the test stand later on. The relative position of the two plates can be adjusted with the aid of a high-precision 3D measuring device.

The first plate and the second plate with the electric motor are fastened to the support frame, whereby the pre-assembled, compact unit is formed. This unit can subsequently be fastened to the mounting plate once the alignment, adjustment and fastening work has been completed.

In particular, the first plate of the unit can be fastened to the mounting plate. For this purpose, a centering device can be provided for centering the first plate relative to the mounting plate. The centering device, for example, can have centering pins in order to be able to fasten the first plate precisely to the mounting plate of the test stand.

As the axis of the electric motor for its part has already been aligned precisely with the first plate beforehand, the axis of the electric motor is therefore also exactly in the position where it must be relative to the test stand shaft in order to achieve the lowest possible offset or error.

A method for aligning the axis of a test specimen relative to the axis of a test stand is specified, comprising the steps of:
providing a first plate and a second plate;
arranging the first plate and second plate with their respective flat sides on top of one another;
fastening the test specimen to the second plate;
measuring the axis of the test specimen and comparing the position of the axis with a predetermined reference position (position, angle) in relation to the first plate;
aligning the axis of the test specimen relative to the first plate by displacing the second plate bearing the test specimen relative to the first plate in order to minimize any deviation of the position of the axis from the reference position;
fastening the first plate with the second plate;
fastening a support frame to the second plate such that the first plate, the second plate, the test specimen, and the support frame form a unit;
fastening the unit to a mounting plate of the test stand.

### BRIEF DESCRIPTION OF THE DRAWINGS

These advantages and features of the invention will be explained in more detail in the following text based on examples with the aid of the accompanying figures, in which:

FIG. 1 shows a schematic side view of a test stand system, with a test stand that is only schematically indicated and an alignment device bearing a test specimen in sectional view;

FIG. 2 shows the alignment device of FIG. 1 with the test specimen in perspective view from above;

FIG. 3 shows the alignment device of FIG. 2 with the test specimen in perspective view from below; and

FIG. 4 shows the alignment device of FIG. 2 without a test specimen.

### DETAILED DESCRIPTION

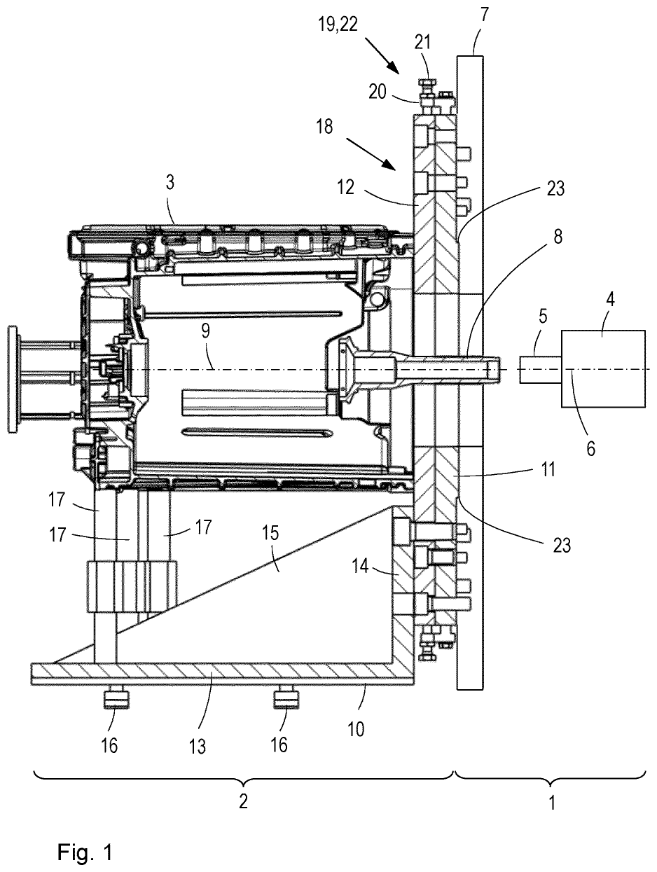

FIG. 1 shows a side view of the schematic set-up of a test stand system with a test stand 1, which is only indicated schematically, and an alignment device 2 according to the invention, to which an electric motor 3 serving as a test specimen is fastened. The alignment device 2 not only serves for aligning the electric motor 3 relative to the test stand 1, but also for pre-assembling and subsequently fastening the electric motor 3 to the test stand 1.

The test stand 1 includes a dynamometer 4, sketched only symbolically in FIG. 1, as a load and drive device. The dynamometer 4, for example, is an electric motor that can be operated as a motor and generator with a motor shaft that constitutes a test stand shaft 5. The dynamometer 4 and the test stand shaft 5 are not drawn to scale in FIG. 1 and serve only to explain the test stand system.

The position of the dynamometer 4 with the test stand shaft 5 also defines a test stand axis 6, which corresponds to the center or rotation axis of the test stand shaft 5.

An element of the test stand 1 is also a mounting plate 7 to which the electric motor 3 is to be fastened for the test procedure.

The electric motor 3, in turn, has a motor shaft 8 that defines a geometric test specimen axis 9.

For the test procedure, the motor shaft 8 of the test specimen (electric motor 3) is connected to the test stand shaft 5 of the dynamometer 4, e.g., via a suitable coupling. In this process, it is particularly important that the test specimen axis 9 and the test stand axis 6 are aligned precisely with one another. Any offset, be it a parallel offset or an angular offset, leads to out-of-round running during the test operation and impairs the measurement results. In the worst case, the test specimen or the test stand can even be damaged if the misalignment is too great.

The alignment device 2 is provided to facilitate alignment and simplify work processes on the test stand.

The alignment device 2 has a support frame 10, a first plate 11, and a second plate 12.

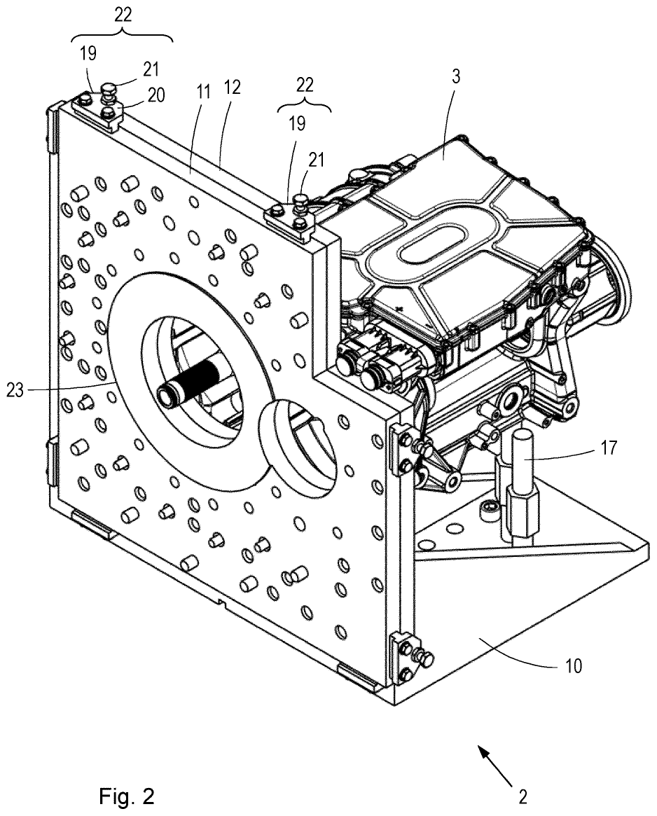

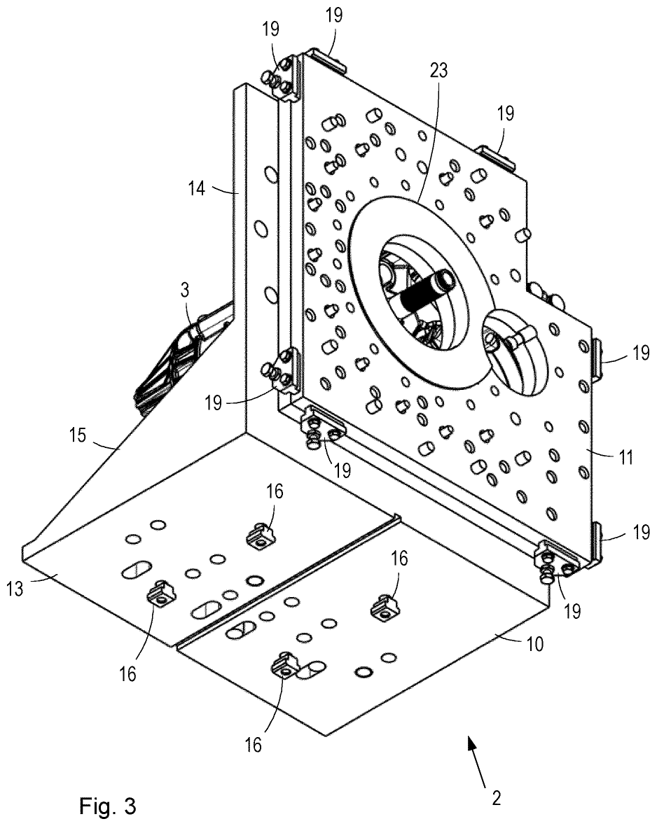

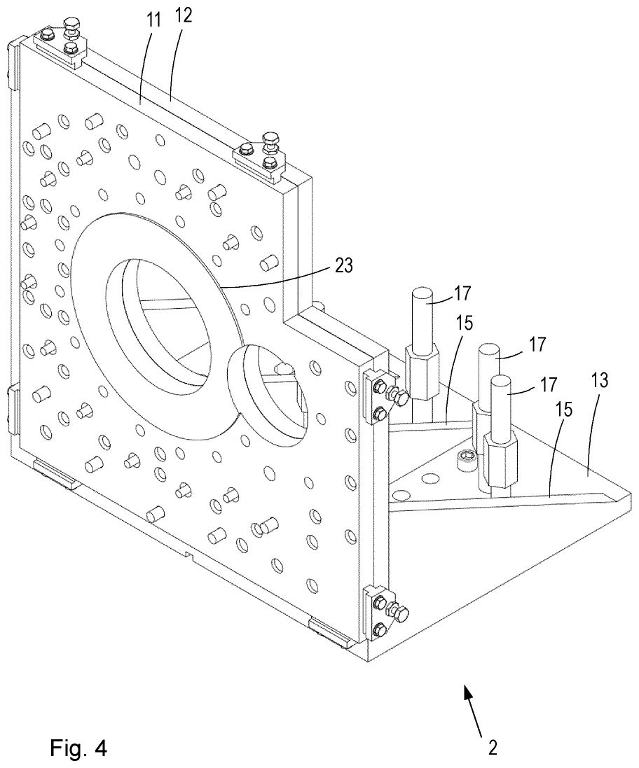

The alignment device 2 is also shown in FIGS. 2 and 3 in different perspectives, together with the electric motor 3. In FIG. 4, the alignment device 2 is depicted without the electric motor 3. Since FIGS. 1 to 4 each show the same alignment device 2, the following description refers to all figures.

The support frame 10 is designed as a stable angular body, comprising a bottom plate 13, a support wall 14 that is vertical when installed on the test stand 1, and reinforcing ribs 15. The elements of the support frame 10, for example, can be formed as a welded construction or milled from solid material. In particular, the underside of the bottom plate 13 must be machined with high precision, as the support frame 10 can be slid onto a corresponding holder on the test stand 1 on this underside, e.g., on a support table provided on the test stand 1. Spring elements 16 are provided for precise guidance of the support frame, which can be inserted into corresponding groove recesses in the support table of the test stand 1 (not depicted).

The second plate 12 is fastened to the end face of the support frame 10, in particular, to the end face of the support wall 14, e.g., by means of a screw connection. The first plate 11 is laid planar on the second plate 12. The first plate 11 and the second plate 12 are connected to one another by screws forming a fastening device and can be screwed together firmly.

The electric motor 3 is fastened to the second plate 12, e.g., via a frontal flange, which is present on the end face of the housing of the electric motor 3. In addition, particularly the rear part of the electric motor 3 facing away from the second plate 12 is supported on the bottom plate 13 by support elements 17. This ensures that the electric motor 3 is reliably fastened to the support frame 10 and the second plate 12 during test stand operation, during which corresponding vibrations and force loads can occur at high speeds.

The support frame 10, the first plate 11 and the second plate 12, together with the electric motor 3 fastened thereto, form a compact unit.

To align the test specimen axis 9 of the electric motor 3, it is possible to displace the second plate 12 in the plane relative to the first plate 11. To do this, the fastening device 18 must be loosened first. To do this, the screws that screw the first plate 11 and the second plate 12 together can be loosened, but only to the extent that the first plate 11 and the second plate 12 can be displaced relative to one another in their contact plane. Any lifting away of the first plate 11 and the second plate 12 should be avoided in this process. The only thing that matters is that they can be displaced relative to one another.

On the end faces of the first plate 11 and the second plate 12, respective screw devices 19 are provided, with a thread mount 20 and a threaded bolt 21 that can be screwed inside it, which together form part of an adjusting device 22.

A total of eight such screw devices 19 are arranged around the circumference of the first plate 11 and the second plate 12, two on each side face, which together form the adjusting device 22.

In this process, the thread mounts 20 can each be fastened to the first plate 11 and bear the threaded bolts 21. By turning the threaded bolts 21, a force can be exerted, via the end face of the threaded bolts 21, on the side faces of the second plate 12 to which it is applied, so that the second plate 12 is displaced relative to the first plate 11 with high precision, namely in accordance with the rotation of the threaded bolts 21. The electric motor 3 fastened to the second plate 12 is displaced accordingly.

During this displacement, the position of the motor shaft 8 and thus of the test specimen axis 9 in relation to a reference position of the first plate 11 can be measured time and again with the aid of a high-precision measuring device. When a state is reached in which the test specimen axis 9 is exactly in the relative position to the first plate 11, in which no further deviation from the reference position (situation, angle) defined by the first plate 11 can be detected, the fastening device 18 can be closed by tightening the connecting screws between the first plate 11 and the second plate 12, so that any displacement of the first plate 11 and the second plate 12 relative to one another is no longer possible.

In this case, the first plate 11, the second plate 12 together with the support frame 10, and the electric motor 3 form a compact, stable unit, with the test specimen axis 9 being exactly at the predetermined place in the predetermined position (reference position). When this compact unit is subsequently fastened to the mounting plate 7 of the test stand 1 via the first plate 11, the test specimen axis 9 and the test stand axis 6 are aligned precisely with one another. A parallel offset or an angular offset can be virtually eliminated in this way.

Pre-assembly and alignment of the electric motor 3, for example, can be carried out, comprising the steps of:
arranging the second plate 12 horizontally on top of the first plate 11 at a pre-assembly workstation not depicted.
placing the test specimen (electric motor 3) on the second plate 12. In this case, the motor shaft 8 protrudes vertically downwards.
measuring the position (situation, direction) of the motor shaft 8 and thus the test stand axis 9 with the aid of a high-precision 3D measuring device.
aligning the motor shaft 8 and thus the test specimen axis 9 through horizontal or flat displacement of the second plate 12 on the first plate 11.
fixing the first plate 11 to the second plate 12 with the aid of the fastening device 18.
rotating the entire apparatus by 90°(including the support frame 10 fastened to the second plate 12).
positioning the spring elements 16 present on the support frame 10 on a corresponding support table of the test stand 1 and sliding the support frame 10 across the support table, with the spring elements 16 being guided within corresponding grooves of the support table.
moving the support frame 10 together with the first plate 11 and the second plate 12 until the first plate 11 comes into contact with the mounting plate 7 of the test stand 1. Thereafter, connecting the plates 11, 12 to the mounting plate 7 with the aid of screw connections.

Appropriate centering elements, e.g., at least two centering bolts, must be provided for exact positioning of the first plate 11 on the mounting plate 7.

In the example shown, centering is achieved by a ring centering with a cylindrical shoulder 23 on the first plate 11. A corresponding hollow cylindrical recess (not depicted) is provided in the mounting plate 7 allocated to the shoulder 23.

1-14. (canceled)

15. An apparatus for aligning an axis of a test specimen relative to an axis of a test stand, the apparatus comprising:
a first plate configured to fasten to a mounting plate of the test stand; and
a second plate configured for fastening the test specimen, wherein the first plate and the second plate are arranged flat on top of one another and fastened by a fastening device, wherein the fastening device allows an alignment state and a fixing state, such that the first plate and the second plate are displaceable parallel relative to one another in the alignment state and are fixed relative to one another in the fixing state; and
an adjusting device configured to displace one of the first plate and the second plate parallel relative to the other plate in the alignment state.

16. The apparatus of claim 15, wherein the fastening device has at least one screw connection which acts between the first plate and the second plate, and wherein the screw connection is firmly tightened in the fixing state and loosened in the alignment state such that the first plate and the second plate are displaceable relative to one another.

17. The apparatus of claim 15, wherein the adjusting device is configured to generate a force between the first plate and the second plate for relative displacement of the first plate and the second plate.

18. The apparatus of claim 15, wherein the adjusting device has a plurality of screw devices, wherein at least one of the screw devices has a thread mount which is fastened to one of the first plate and the second plate, wherein a screw bolt can be screwed inside the thread mount, and wherein one end face of the screw bolt acts on that one of the first plate and the second plate to which the thread mount is not fastened, such that a force can be applied to that one of the first plate and the second plate to which the thread mount is not fastened.

19. The apparatus of claim 18, wherein the thread mount and/or the screw bolt are arranged on a side face of the respective plate, and wherein the side face is perpendicular to a contact surface where the first plate and the second plate are flatly in contact.

20. The apparatus of claim 15, wherein a geometry of the first plate and the second plate each corresponds to a plate-shaped cuboid, each having two plate surfaces parallel to one another and four side faces connecting the two plate surfaces, and wherein the adjusting device has eight screw devices, two of which are each arranged on a side face of a plate at a distance from one another.

21. The apparatus of claim 15, wherein the test specimen is an electric motor.

22. The apparatus of claim 15, further comprising:
a support frame fastened to the second plate.

23. The apparatus of claim 22, wherein a plurality of support elements provided on the support frame is configured to support the test specimen fastened to the second plate.

24. A test stand system, comprising:
an electric motor test specimen;
a test stand configured to test the electric motor;
a test stand shaft, to which a shaft of the electric motor can be fastened, configured to transmit a motion of the electric motor to the test stand;
a mounting plate provided on the test stand; and
the apparatus of claim 15 configured as alignment device, the alignment device configured to fasten the electric motor to, and align the electric motor with, the mounting plate.

25. The test stand system of claim 24, wherein the first plate, the second plate, the electric motor fastened to the second plate, and the support frame constitute a pre-assembled unit which can be fastened as a single unit to the mounting plate.

26. The test stand system of claim 24, wherein the first plate is configured to be fastened to the mounting plate.

27. The test stand system of claim 24, further comprising:
a centering device configured to center the first plate relative to the mounting plate.

28. A method for aligning an axis of a test specimen relative to an axis of a test stand, the method comprising:
providing a first plate and a second plate;
arranging the first plate and second plate with respective flat sides on top of one another;
fastening the test specimen to the second plate;
measuring the axis of the test specimen and comparing a position of the axis of the test specimen with a predetermined reference position in relation to the first plate;
aligning the axis of the test specimen relative to the first plate, by displacing the second plate bearing the test specimen relative to the first plate in order to minimize any deviation of the position of the axis of the test specimen from the reference position;
fastening the first plate with the second plate;
fastening a support frame to the second plate such that the first plate, the second plate, the test specimen, and the support frame form a unit; and
fastening the unit to a mounting plate of the test stand.
